(19) United States
(12) Patent Application Publication
(10) Pub. No.: US 2025/0157846 A1
(43) Pub. Date: May 15, 2025

(54) Wafer Singulation Film

(71) Applicant: Robert Bosch GmbH, Stuttgart (DE)

(72) Inventors: Franz Laermer, Weil Der Stadt (DE); Daniel Sebastian Podbiel, Rutesheim (DE)

(21) Appl. No.: 18/837,525

(22) PCT Filed: Feb. 10, 2023
(86) PCT No.: PCT/EP2023/053263

§ 371 Date: Aug. 9, 2024

(30) Foreign Application Priority Data
Feb. 10, 2022 (DE) 10 2022 201 365.4

(51) Int. Cl. H01L 21/683; C09J 5/00; C09J 7/00; H01L 21/78

(52) U.S. Cl. CPC H01L 21/6836; C09J 5/00; C09J 7/00; H01L 21/78; C09J 2203/326; C09J 2301/204; C09J 2301/416

(57) ABSTRACT

A wafer singulation film includes a carrier film which has an adhesive layer on one side. The adhesive layer has a microstructuring with adhesive regions and non-adhesive regions. The microstructuring of the adhesive layer is complementary to a microstructuring on the surface of the wafer.

The present invention relates to a wafer singulation film which is adhered to a wafer in order to fix individual chips during singulation. The invention also relates to a manufacturing method for a wafer singulation film. Finally, the invention relates to the use of the wafer singulation film for the singulation of chips from the wafer.

### PRIOR ART

In chip production, a large number of chips are manufactured on one wafer. The chips can contain MEMS elements, for example. After the wafer has been processed, it is singulated into individual chips so that they can be assembled and packaged separately. Various singulation methods are known for this purpose, such as laser singulation (stealth dicing) or mechanical sawing.

Carrier films are already known which have an adhesive layer with which the carrier film is stuck to the wafer. The carrier films are used, for example, to expand the wafer and/or are used as a carrier element to fix the individual chips during singulation and then detach them from the carrier film in a defined manner.

DE 103 42 981 A1 provides a first film, also known as an adhesive film, which is bonded to the chips of the wafer. A peel-off film is applied to the first film. By removing the peel-off film, the first film is also peeled off in predetermined regions that should not remain on the wafer. It is intended that partially or selectively individual regions of the wafer are not provided with the first adhesive film. The individual regions should be assigned to individual chips. Consequently, structuring with regions the size of entire chips is planned.

When the peel-off film is removed, some chips stick and are thus singulated, while other chips remain on the wafer.

With the known carrier films with an adhesive layer, the adhesive layer covers the entire chip and therefore also functional elements, such as sensor surfaces and chemically sensitive layers, which can be contaminated by the adhesive or damaged by the bonding.

### DISCLOSURE OF THE INVENTION

A wafer singulation film for a wafer is proposed. The wafer singulation film has a thin carrier film with a microstructured adhesive layer applied to one side, with which the carrier film is bonded to the wafer, and is used to expand the wafer and/or is used as a carrier element to fix individual chips during singulation and then detach them from the carrier film in a defined manner. The carrier film can preferably have a thickness of between 35 μm and 300 μm, particularly preferably between 50 μm and 150 μm, and can be stretched when lateral force is applied. The adhesive layer can preferably have a thickness of between 3 μm and 30 μm, particularly preferably between 5 μm and 20 μm. The adhesive layer has a microstructuring with adhesive regions and non-adhesive regions. The microstructuring of the adhesive layer is of the same size as the functional elements, e.g. the sensor surfaces or chemically sensitive layers, the chips. Preferably, the non-adhesive regions have a lateral dimension in at least one spatial dimension in the range from 30 μm to 3000 μm and particularly preferably in the range from 100 μm to 1000 μm. The non-adhesive regions are therefore the same size as the functional elements of the chips and are therefore significantly smaller than the chips themselves. The microstructuring is complementary or at least partially complementary to a microstructuring on the surface of the wafer with which the functional elements of the chips are formed. This means that the adhesive layer of the wafer singulation film is microstructured in such a way that-after aligning the microstructured surface of a wafer with the wafer singulation film with the microstructured adhesive layer-when the wafer and the wafer singulation film are bonded, predetermined regions of the microstructured surface of the wafer are covered by the non-adhesive regions of the adhesive layer of the wafer singulation film. The microstructuring on the surface of the wafer can be determined in advance and is already known when the wafer is designed. This means that the wafer itself is not necessary, but only its layout in order to determine the microstructuring.

In this way, the individual chips are reliably fixed to the wafer singulation film during or after singulation of the wafer. On the other hand, the particularly sensitive functional elements, which are microstructured on the surface of the wafer, are prevented from being adversely affected in their properties or the resulting functionality by contact with the adhesive layer or subsequent detachment from the adhesive layer. For example, when the wafer is detached from the wafer singulation film, a functional coating present in partial regions of the surface of the wafer is prevented from being at least partially detached from the surface of the wafer or residues of the adhesive layer remain on the functional coating, which in both cases can lead to a restriction or reduction in the functionality of the coating. This is particularly advantageous for chemical sensors or gas sensors that have a chemically sensitive layer for identifying gases. Any contamination of the chemically sensitive layer massively impairs the function of the gas sensor. This opens up new possibilities for designing the microstructurings on the wafer by using the wafer singulation film.

The microstructuring can be advantageously achieved by at least partially removing the adhesive layer in the non-adhesive regions. The adhesive layer remains unchanged in the adhesive regions. This means that the adhesive layer does not come into contact with the functional elements in the specified regions of the surface of the wafer.

The removal of the adhesive layer in the non-adhesive regions can be achieved, for example, by shaving off precisely these regions of the adhesive layer using an ultrashort pulse laser in order to achieve a highly defined removal of the adhesive layer in these regions by so-called “ablation”. The carrier film underneath remains intact, so that a continuous layer remains, which forms the structural basis of the wafer singulation film. By using ultrashort laser pulses, in particular with a (medium) wavelength in the ultraviolet wavelength range, for example between 200 and 400 nm, in particular 355 nm, a particularly reliable ablation of the adhesive layer can be achieved in many cases, since a high absorption of the electromagnetic radiation at the adhesive layer can be achieved by the adhesive layer and in particular the polymer carrier layer underneath.

The use of ultrashort laser pulses for structuring the adhesive layer of the wafer singulation film enables a particularly precise and “clean” (without repositioning) microstructuring of the adhesive layer of the wafer singulation film, which is complementary to the microstructurings introduced into the wafer. On the other hand, a pulse duration in the range of less than 20 picoseconds can sufficiently minimize thermal heat input and prevent the resulting thermally induced deformation of the wafer singulation film. In addition, a particularly variable, individually adaptable geometry of the microstructuring of the adhesive layer of the wafer singulation film can be achieved, which is optimized for the microstructuring of the wafer to be singulated. Compared to the production of a wafer singulation film by means of punching, for example, possible deformation of the wafer singulation film due to mechanical force can also be avoided.

The microstructuring can be advantageously achieved by having the adhesive layer in a passivated form in the non-adhesive regions. During passivation, the adhesive layer hardens, cross-links and/or polymerizes, so that there is no adhesive effect in these regions. This deprives the adhesive layer in the non-adhesive regions of its active adhesive properties and transforms it into a glass-like passive layer. This glass-like layer can then touch the functional elements in the specified regions on the surface of the wafer, but can no longer contaminate or damage them.

Ultraviolet radiation can be used to passivate the adhesive layer. For example, short-wave laser radiation in the ultraviolet range can be used for this purpose, which irradiates the non-adhesive regions locally. Passivation, i.e. hardening, cross-linking and/or polymerization, in the non-adhesive regions of the adhesive layer can be achieved by locally defined exposure to UV radiation. In addition to a frequency-multiplied Nd:YAG laser (neodymium yttrium aluminum garnet laser), excimer lasers that emit light pulses with pulse durations in the nanosecond range with wavelengths of 308 nm (XeCl), 248 nm (KrF) or 193 nm (ArF) and energies in the range of 10 mJ to 1 J can also be used as light sources.

In addition, a mask exposure unit can be used in an advantageous way, which allows for exposure and thus passivation of the adhesive in partial regions of the adhesive layer using a mask. The use of a mask is particularly suitable for producing a large number of wafer singulation films with an identical microstructured adhesive layer in a short time. The mask exposure device may also have an alignment device in order to align a microstructured wafer appropriately, i.e. for example complementary to the microstructuring of the adhesive layer of the wafer singulation film, and to enable defined bonding of the wafer and the wafer singulation film.

Advantageously, the adhesive layer is an adhesive layer based on an acrylate adhesive. Exposure to a sufficient dose of ultraviolet radiation and the resulting cleavage of photoinitiators into free radicals triggers the formation of polymer chains so that passivation, i.e. hardening, crosslinking and/or polymerization of the adhesive in the adhesive layer takes place.

Both types of microstructuring can also be combined. There is therefore a microstructuring of the adhesive layer, which is realized both by at least partially removing the adhesive layer in the non-adhesive regions and by passivating the adhesive layer in these non-adhesive regions. For this purpose, the ultrashort pulse laser used to remove the adhesive layer can use a wavelength in the ultraviolet range, so that passivation is carried out in addition to removal. In particular, residues of the adhesive layer that may remain in this region after removal can be passivated.

The microstructuring of the adhesive layer can have non-adhesive regions that are in the form of strips. Preferably, the strip-shaped non-adhesive regions alternate in one direction with the adhesive regions, which are also in the form of strips. This makes it easy to produce the microstructuring by scanning the non-adhesive regions in strips in a particularly simple and fast way. Particularly when using an ultrashort pulse laser, this can perform the strip-shaped scanning without the need to block (shutter) the laser beam in between.

Alternatively, the microstructuring of the adhesive layer can have a plurality of non-adhesive regions, in particular of the same shape, which are arranged periodically along a predeterminable grid. Preferably, the non-adhesive regions alternate with adhesive regions that are also arranged in a grid. The grid spacing between two similarly shaped regions along the grid in at least one spatial dimension is preferably in the range between 50 μm and 15000 μm and particularly preferably in the range between 200 μm and 2000 μm. The microstructuring can be easily realized using a step-and-repeat method. Especially when using an ultrashort pulse laser, it can pass over the wafer singulation film several times and perform ablation or passivation each time. The grid is particularly suitable for singulating the wafer into rectangular, especially square, chips, which are often used in practice and allow particularly simple singulation of the wafer into chips, for example by means of stealth dicing and expansion of the wafer on the wafer singulation film.

Preferably, the wafer singulation film is clamped in a tensioning frame with a pretensioning. The pretensioning is selected to be sufficiently high to ensure that there is no permanent or prolonged contact between the surface of the wafer and the adhesive layer as a result of “sagging”. For example, the mechanical resonance frequency of the clamped wafer singulation film can be used to select the pretensioning, which should preferably be between 20 Hz and 200 Hz and particularly preferably between 50 Hz and 100 Hz. On the one hand, the pretensioning ensures that the film is flat, which is a prerequisite for precise optical processing by the laser. Secondly, it ensures that the adhesive regions of the wafer singulation film do not “sag” on the wafer or rest on it over a longer period of time.

Finally, the invention also relates to a wafer singulation film, as described above, with a wafer. The wafer has a microstructuring on its surface. The microstructuring is formed by the functional elements, e.g. the sensor surfaces or the chemically sensitive layers of the chips on the wafer. The wafer singulation film has a carrier film with an adhesive layer on one side. The adhesive layer has a microstructuring with adhesive regions and non-adhesive regions. The microstructuring of the adhesive layer is complementary or at least partially complementary to the microstructuring on the surface of the wafer. For a detailed explanation of the elements and the resulting benefits, reference is made to the description above.

In addition, a method for producing a wafer singulation film for a wafer is proposed. A carrier film is provided. The carrier film has a homogeneous adhesive layer on one side, which is applied to the wafer. The adhesive layer is then microstructured with adhesive regions and non-adhesive regions. The microstructuring of the adhesive layer is of the same size as the functional elements, e.g. the sensor surfaces or chemically sensitive layers, the chips. The non-adhesive regions are therefore the same size as the functional elements of the chips and are therefore significantly smaller than the chips themselves. The microstructuring is complementary to a microstructuring on the surface of the wafer with which the functional elements of the chips are formed. This means that the adhesive layer of the wafer singulation film is microstructured in such a way that—after aligning the microstructured surface of a wafer with the wafer singulation film with the microstructured adhesive layer—when the wafer and the wafer singulation film are bonded, predetermined regions of the microstructured surface of the wafer are covered by the non-adhesive regions of the adhesive layer of the wafer singulation film.

Before the structuring of the adhesive layer is carried out, the microstructuring of the surface of the wafer can preferably be recorded.

For example, precisely those regions with a sensitive functional coating that could be adversely affected by contact with the adhesive layer of the wafer singulation film are detected. Based on the detected regions, the complementary microstructuring of the adhesive layer on the carrier film is then structured. The non-adhesive regions of the adhesive layer are formed according to the detected regions of the surface in order to prevent contact with the sensitive coating of the substrate.

Before the structuring of the adhesive layer is carried out, the carrier film with the adhesive layer can also preferably be clamped in a tensioning frame with a pretensioning. In particular, this is a tensioning frame, which is conventionally used for singulating the wafer. By clamping the carrier film with a homogeneous adhesive layer onto the tensioning frame, it can be ensured that the top side of the carrier film and the adhesive layer are (almost) in one plane in a sufficiently pretensioned state. For example, the mechanical resonance frequency of the clamped wafer singulation film can be used to select the pretensioning, which should preferably be between 20 Hz and 200 Hz and particularly preferably between 50 and 100 Hz. On the one hand, the pretensioning ensures that the film is flat, which is a prerequisite for precise optical processing by the laser. Secondly, it ensures that the adhesive regions of the wafer singulation film do not “sag” on the wafer or rest on it over a longer period of time. This enables particularly simple, reliable and precise microstructuring of the adhesive layer, for example using a laser micromachining system.

The microstructuring can be advantageously achieved by at least partially removing the adhesive layer in the non-adhesive regions. The adhesive layer remains unchanged in the adhesive regions. This means that the adhesive layer does not come into contact with the functional elements in the specified regions of the surface of the wafer.

Preferably, the adhesive layer is microstructured by removing it using ultrashort laser pulses with a pulse duration of less than twenty picoseconds, for example. By using ultrashort laser pulses, the thermal effect on the carrier film during processing of the adhesive layer can be sufficiently minimized so that undesired thermally induced deformation of the wafer singulation film can be prevented and thus sufficient dimensional accuracy of the complementary microstructuring can be ensured. The wavelength of the laser is preferably selected to suit the optical absorption characteristics of the adhesive layer. For example, a mode-locked frequency-converted Nd:YAG laser can be used as a pulsed laser light source or short-pulse laser, wherein the frequency conversion takes place in a tripling of the light frequency or a thirding of the laser wavelength from primarily 1064 nm to 354.7 nm in a sequence of non-linear optical processes in converter crystals (e.g. potassium dihydrogen phosphate KDP, barium betaborate BBO).

The microstructuring can be advantageously achieved by having the adhesive layer in a passivated form in the non-adhesive regions. During passivation, the adhesive layer is hardened, cross-linked and/or polymerized so that there is no adhesive effect in these regions. This deprives the adhesive layer in the non-adhesive regions of its active adhesive properties and transforms it into a glass-like passive layer. This glass-like layer can then touch the functional elements in the specified regions on the surface of the wafer, but can no longer contaminate or damage them.

Preferably, the adhesive layer is microstructured by passivation by means of exposure to a sufficient dose of ultraviolet radiation and the resulting cleavage of photoinitiators into free radicals, which triggers the formation of polymer chains in these partial regions, so that the passivation (hardening/crosslinking/polymerization) of the adhesive of the adhesive layer takes place.

Both types of microstructuring can also be combined. There is therefore a microstructuring of the adhesive layer, which is realized both by at least partially removing the adhesive layer in the non-adhesive regions and by passivating the adhesive layer in these non-adhesive regions.

Preferably, the carrier film of the wafer singulation film has a sufficiently high optical absorption in the wavelength range of the laser, so that passivation or removal of the adhesive layer can be carried out in particular using the above-mentioned ultrashort pulse laser with a suitable wavelength.

If the film is based on a polymer, the above-mentioned pulsed laser light source or short-pulse laser can use a wavelength in the ultraviolet radiation range of the electromagnetic spectrum. For example, a wavelength of 354.7 nm from a frequency tripled Nd:YAG laser can be used. Another advantage of short-pulse laser ablation is the avoidance of ejections and repositioning of ablated material around the cutting edge.

It may be provided to additionally implement particles, for example soot particles or other nanoparticles, in the wafer singulation film, which also cause optical absorption of the film at other wavelengths, for example in the visible range or the near infrared range of the electromagnetic radiation spectrum. Consequently, different types of ultrashort pulse lasers can be used for microstructuring the adhesive layer, for example pulsed Nd:YAG lasers at their primary wavelength of 1064 nm in the near infrared range.

The above-mentioned wafer singulation film can be used to singulate chips from a wafer. For this purpose, the wafer singulation film is provided with the adhesive layer with microstructuring, which is complementary to the microstructuring on the surface of the wafer. The wafer singulation film and the wafer are then aligned in such a way that the microstructuring of the adhesive layer matches the microstructuring on the surface of the wafer. The surface of the wafer is then bonded to the wafer singulation film via the adhesive layer or, conversely, the wafer singulation film with the adhesive layer is bonded to the surface of the wafer. Finally, the singulation of the wafer is carried out.

The wafer singulation film according to the invention can advantageously be applied to the wafer in just a single adhesion step. In particular, for example, compared to the use of a first non-structured carrier film layer and a second microstructured adhesive layer with through-hole recesses, advantageously no joining of several film layers is required after microstructuring of the adhesive layer in order to form a wafer singulation film with a microstructured adhesive layer. Furthermore, with a gas-tight sealing of a wafer surface with the wafer singulation film, the volume of air (or a gas) trapped between the surface of the wafer and the wafer singulation film is particularly low, since the microstructured adhesive layer can have a particularly low layer thickness due to the combination of the adhesive layer with a carrier film. This can advantageously reduce the occurrence of air (or gas) entrapment between the wafer and the wafer singulation film when the wafer is adhered to the wafer singulation film.

### BRIEF DESCRIPTION OF THE DRAWINGS

Exemplary embodiments of the invention are shown in the drawings and explained in more detail in the following description.

FIGS. 1 A, B each show a side view of a wafer singulation film according to an embodiment of the invention.

FIG. 2 shows a side view of a wafer singulation film according to a further embodiment of the invention.

FIGS. 3 A, B each show a side view of the wafer singulation film and a wafer during (FIG. 3 A) and after (FIG. 3 B) adhesion.

FIGS. 4 A, B each show a top view of the wafer singulation film before (FIG. 4 A) and after (FIG. 4 B) adhesion with the wafer.

FIGS. 5 A, B each show a flow chart of embodiments of a manufacturing method of the wafer singulation film according to the invention.

FIG. 6 shows a flow chart of an embodiment of a method according to the invention for using the wafer singulation film for singulating chips from a wafer.

FIGS. 7 A-E schematically show the manufacturing method and the application on the wafer by means of cross-sectional views.

FIGS. 8 A-D show in a schematic manner the implementation of the manufacturing method and the application on the wafer by means of top view illustrations according to one embodiment.

FIGS. 9 A-D show in a schematic manner the implementation of the manufacturing method and the application on the wafer by means of top view representations according to a further embodiment.

### EXEMPLARY EMBODIMENTS OF THE INVENTION

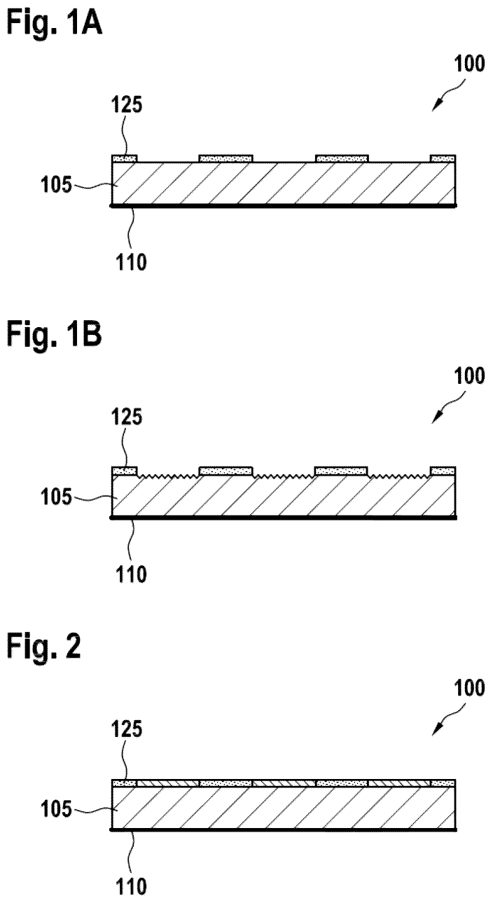

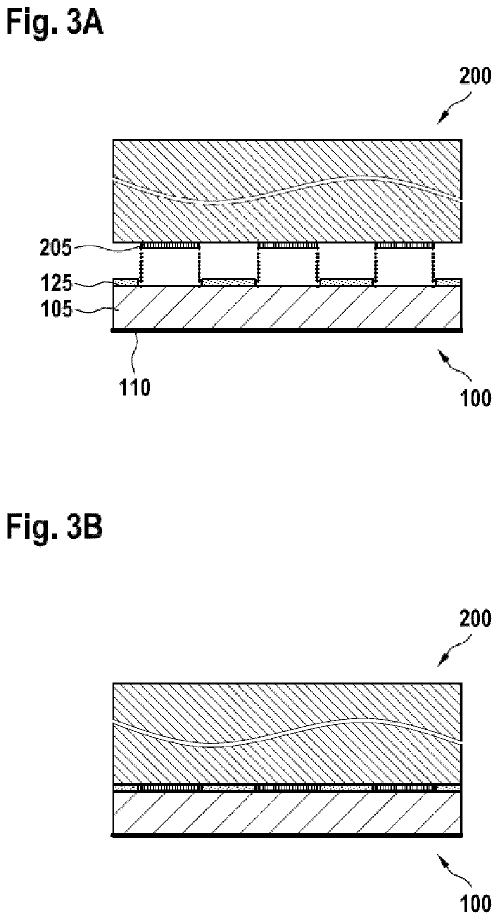

FIGS. 1 A, B each show a cross-sectional view of an exemplary embodiment of the wafer singulation film 100 according to the invention with a microstructured adhesive layer 125 according to one embodiment. The wafer singulation film 100 comprises a carrier film 105 and the microstructured adhesive layer 125, which is arranged on one side of the carrier film 105. Furthermore, the wafer singulation film 100 has a silicone coating 110, which is arranged on the other side of the carrier film 105. The silicone coating 110 serves to enable the wafer singulation film 100 to be transported or stored in wound form and to enable the wafer singulation film 100 to be unrolled easily despite the adhesive layer 125. In this exemplary embodiment, the microstructuring of the adhesive layer 125 is realized in such a way that in predetermined regions of the wafer singulation film 100 the adhesive layer 125 has been completely removed from the carrier film 105, while in other regions the adhesive layer 125 is present in homogeneous form on the carrier film. The regions in which the adhesive layer 125 has been removed thus no longer adhere to a wafer (see FIG. 3 A, B) and are thus referred to as non-adhesive regions. The regions in which the adhesive layer 125 is still present are referred to as adhesive regions.

FIG. 1 B shows that the carrier film 105 is partially removed in the non-adhesive regions due to the manufacturing process. Thus, a thinning of the carrier film 105 may be present in these non-adhesive regions. In addition, the surface of the carrier film 105 has an increased roughness in the non-adhesive regions. The increased surface roughness in the non-adhesive regions may in particular also be associated with a change in the optical properties in these regions of the wafer singulation film 100. This is particularly advantageous when aligning the wafer singulation film 100 with the microstructured adhesive layer 125 relative to a microstructured wafer (see FIG. 3), in order to enable particularly simple optical alignment thanks to the visibility of the structures in the wafer singulation film 100.

FIG. 2 shows a further embodiment of the wafer singulation film 100 according to the invention with a microstructured adhesive layer 125. This embodiment differs from the previous embodiment in that a microstructuring of the adhesive layer 125 is realized in such a way that in predeterminable regions of the wafer singulation film 100 the adhesive layer 125 is passivated, while in other regions the adhesive layer 125 is present in homogeneous and non-passivated form on the carrier film 125. Passivation hardens, cross-links and/or polymerizes the adhesive layer 125 so that it loses its adhesive properties and non-adhesive regions are formed. In the regions that have not been passivated, the adhesive layer 125 retains its adhesive properties, so that there are still adhesive regions here. As the adhesive layer 125 is not removed, its surface remains essentially flat.

Irrespective of the embodiments described above, the carrier film 105 comprises, for example, plasticized polyvinyl chloride (PVC) and has a thickness of, for example, 65 μm. The adhesive layer 125 on the upper side of the carrier film 105 is, for example, acrylate-based and has, for example, a thickness of 10 μm.

FIGS. 3 A, B each show a cross-sectional view of an adhesion of the wafer singulation film 100 with the microstructured adhesive layer 125 and a wafer 200 with a surface coating 205, which is present in partial regions of a surface of the wafer 200. In FIG. 3 A, the wafer 200 is applied to the wafer singulation film 100 from the side of the adhesive layer 125. The wafer 200 is adhesively bonded to the wafer singulation film 100 by the adhesive layer 125 (see FIG. 3 B).

As described above, the adhesive layer 125 of the wafer singulation film 100 has a microstructuring, so that in the adhesive regions an adhesive bond is produced between the adhesive layer 125 and the surface of the wafer 200 and in the non-adhesive regions, due to the recesses in the adhesive layer 125 or the passivation of the adhesive layer 125, an interaction of the adhesive layer 125 with the surface of the wafer 200 is avoided. In the non-adhesive regions, the surface of the wafer 200 may be in contact with the carrier film 105 of the wafer singulation film 100 and/or with the passivated regions of the adhesive layer 125 of the wafer singulation film 100.

In this case, the microstructuring of the adhesive layer 125 of the wafer singulation film 100 is formed complementary (or at least partially complementary) to the surface coating 205 of the wafer 200. The wafer 200 and the wafer singulation film 100 can be aligned with respect to each other in such a way that the partial regions with the surface coating 205 of the wafer 200 do not overlap with the adhesive regions of the adhesive layer 125 of the wafer singulation film 100.

Thus, if the wafer 200 is suitably aligned with the wafer singulation film 100, the surface coating 205 of the wafer 200 is prevented from coming into contact with the active adhesive layer 125 of the wafer singulation film 100 when the wafer 200 is adhered to the wafer singulation film 100. In this way, undesired impairment of the integrity of the surface coating 205 by contact with the adhesive regions of the adhesive layer 125 is avoided. In addition, it is prevented that residues of the adhesive layer 125 remain on the surface coating 205 when the wafer 200 is peeled off and when the chips (not shown here) of the wafer 200 are singulated and/or parts of the surface coating 205 are detached in an undesirable manner by the adhesive forces to the adhesive layer 125. Both can adversely affect the functionality of the surface coating 205.

FIG. 3 B shows the completed bonding of the wafer 200 with a wafer singulation film 100. The wafer 200 is glued to the adhesive layer 125 of the wafer singulation film 100. Due to the design of the microstructured adhesive layer 125, the adhesive regions of the adhesive layer 125 only come into contact with the partial regions of the surface of the wafer 200 on which there is no surface coating 205 after the wafer 200 has been adhered to the wafer singulation film 100. The partial regions of the surface of the wafer 200, which have the surface coating 205, only come into contact with the non-adhesive regions of the adhesive layer 125, i.e. the recesses of the adhesive layer and/or the passivated regions of the adhesive layer 125. This ensures the functionality of the surface coating 205, which would be adversely affected by permanent contact with the adhesive regions of the adhesive layer 125 of the wafer singulation film 100.

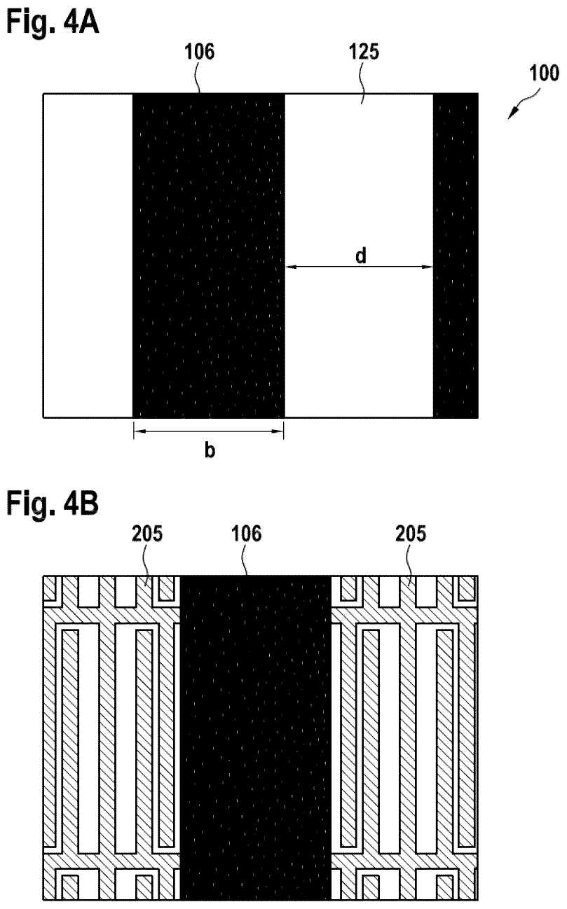

FIG. 4 A shows a top view of the wafer singulation film 100, as shown in FIG. 1 B, created using a microscope. In this exemplary embodiment, the wafer singulation film 100 has a microstructuring of the adhesive layer 125 in the form of strips. In this case, the non-adhesive regions have been realized by removing the adhesive layer 125, wherein a roughness of the surface of the carrier layer 105 is generated here, which becomes visible as dark regions 106 due to the reduced optical transmittance of the wafer singulation film 100. The non-adhesive regions of the adhesive layer 125, which are shown here as dark regions 106, are oriented vertically in strips and each have a width b of about 1000 μm and a distance d of about 1000 μm from one another. The adhesive regions of the adhesive layer 125 are also arranged in strips and thus also have a width d of approximately 1000 μm.

FIG. 4 B shows a top view of the wafer 200 bonded to the wafer singulation film 100 by means of a microscope, as shown in FIG. 3 B. In this exemplary embodiment, the wafer singulation film 100 also has a strip-shaped microstructuring of the adhesive layer 125, according to FIG. 4 A. The non-adhesive regions of the adhesive layer 125 are also realized by removing the adhesive layer 125 and thus again appear as dark regions 106. They are oriented vertically in the form of strips. The adhesive regions of the adhesive layer 125 are also oriented vertically in the form of strips. The wafer 200 has a complex microstructured surface coating 205. In this case, predetermined partial regions of the microstructuring 205 of the wafer 200 overlap with the strip-shaped non-adhesive regions of the wafer singulation film 100. In this way, undesired interaction of the adhesive layer 125 with the partial regions of the wafer 200 in which a surface coating 205 is present can be avoided.

In other exemplary embodiments not shown, the wafer singulation film 100 has a grid-like microstructuring of the adhesive layer 125. Several similarly shaped non-adhesive regions and several similarly shaped adhesive regions are arranged alternately in a periodic manner along a predeterminable grid. The grid spacing between two similarly shaped regions along the grid in at least one spatial dimension is 1000 μm, for example.

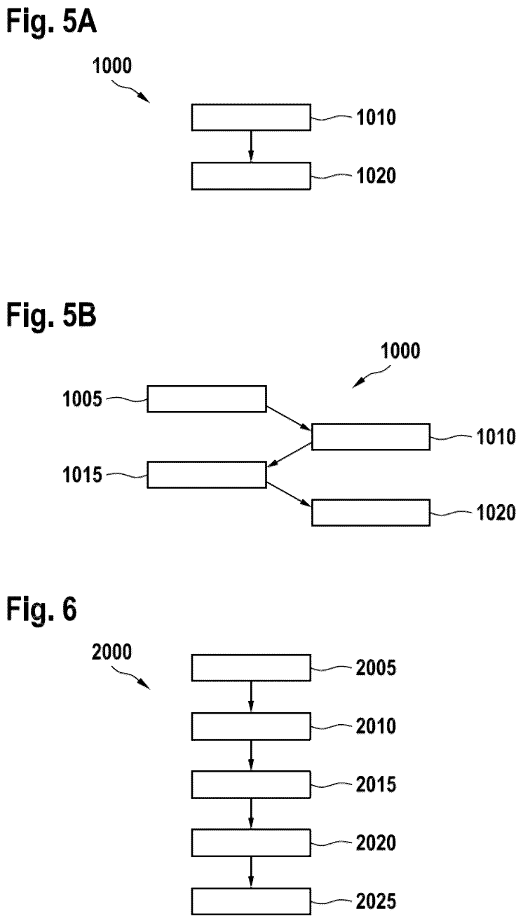

FIGS. 5 A, B show flow charts of an embodiment of the manufacturing method 1000 according to the invention for a wafer singulation film 100. Initially, a carrier film 105 with a homogeneous adhesive layer 125 is provided 1010. This is followed by structuring 1020 of the microstructuring of the adhesive layer 125 on the carrier film 105.

In an exemplary embodiment, the structuring 1020 of the microstructuring of the adhesive layer 125 is performed by removing predeterminable regions of the wafer singulation film 100. The regions that have been removed have no significant or at least significantly reduced adhesive strength and are referred to as non-adhesive regions. In contrast, the adhesive layer 125 is not removed in other regions. The adhesive layer 125 continues to exhibit its adhesive properties in these regions and these regions are referred to as adhesive regions. Removal is carried out using an ultrashort pulse laser, wherein the adhesive layer is removed in predetermined partial regions by shaving off predeterminable regions of the wafer singulation film 100 with the laser beam. For this purpose, the wafer singulation film 100 can, for example, be arranged on a table that can be moved in two spatial directions and/or the laser beam can be deflected by means of mirror optics.

The laser is merely an example of a frequency tripled pulsed Nd:YAG laser. The pulse duration of the laser is for example about 10 picoseconds, the wavelength of the laser is for example 355 nm, the spot diameter of the laser is for example 18 μm (FWHM), the repetition rate of the laser is for example 500 kHz, the average radiation power of the laser is for example 800 mW, the pulse energy is for example 1.6 μJ, the traversing speed of the laser beam on the surface of the wafer singulation film is for example 400 mm/s, which corresponds to a pulse overlap of about 95%, the distance between the lines along which the wafer singulation film 100 is scanned is, for example, 10 μm and the orientation of the lines along which the wafer singulation film 100 is scanned is, for example, parallel to the orientation of the strip-shaped regions according to FIG. 4 in which the adhesive layer 125 is removed.

In particular, a low pulse duration in the picosecond range (or femtosecond range) can advantageously prevent thermal deformation of the wafer singulation film 100 during microstructuring of the adhesive layer 125. In particular, a highly defined ablation of the adhesive layer 125 is thus possible, wherein in particular thermal damage to the surrounding material and thus in particular a detrimental impairment of the dimensional stability of the wafer singulation film 100 can be avoided.

A wavelength in the ultraviolet range, in particular between 200 nm and 400 nm, e.g. 355 nm, can ensure a high absorption of the laser radiation on the adhesive layer to be structured. In this way, a reliable and defined removal of the adhesive layer 125 can be achieved.

A spatially precise microstructuring of the adhesive layer 125 can be achieved by a spot diameter of the laser beam in the plane of the adhesive layer 125 to be structured in the range of less than 20 μm. In order to achieve the smallest possible spot diameter in the plane of the adhesive layer 125, this corresponds in particular (almost) to a focal plane of the optics of the laser beam.

In an exemplary embodiment, the structuring 1020 of the microstructuring of the adhesive layer 125 is performed by removing within predeterminable regions of the wafer singulation film 100. The regions that have been removed have no significant or at least significantly reduced adhesive strength and are referred to as non-adhesive regions.

In contrast, the adhesive layer 125 is not removed in other regions. The adhesive layer 125 continues to exhibit its adhesive properties in these regions and these regions are referred to as adhesive regions.

In an alternative embodiment, the structuring 1020 of the microstructuring of the adhesive layer 125 is performed by passivating predeterminable regions of the adhesive layer 125 of the wafer singulation film 100 by hardening, crosslinking and/or polymerizing the adhesive of the adhesive layer 125. The passivated regions have no significant or at least significantly reduced adhesiveness and are referred to as non-adhesive regions. In contrast, the adhesive layer 125 is not passivated in other regions. The adhesive layer 125 continues to exhibit its adhesive properties in these regions and these regions are referred to as adhesive regions.

Passivation of the adhesive layer 125 is caused, for example, in the case of an adhesive layer 125 based on an acrylate adhesive, by exposure to a sufficient dose of ultraviolet radiation and cleavage of photoinitiators into free radicals. This triggers the formation of polymer chains so that the adhesive of the adhesive layer 125 is passivated. The high energy of ultraviolet photons is particularly advantageous for triggering polymerization reactions by inducing free radicals. After passivation of the adhesive layer by hardening, crosslinking and/or polymerization of the adhesive of the adhesive layer 125 in predetermined regions, an interaction of the passivated non-adhesive regions with the sensitive surface microstructuring of the wafer 200 can be advantageously sufficiently reduced when the wafer 200 is adhered to the wafer singulation film 100.

Passivation of the adhesive layer 125 by exposure to a sufficient dose of ultraviolet radiation can be achieved, for example, in a similar way to that described above, by shaving off the surface with a laser beam of ultraviolet wavelength or by using a mask exposure device with a mask and an ultraviolet radiation source such as a mercury vapor lamp or an excimer laser.

According to FIG. 5 B, in a further exemplary embodiment, the method 1000 comprises the steps of detecting 1005 the microstructuring of the surface of the wafer 200 and stretching 1015 the wafer singulation film 100 in a tensioning frame 500.

When detecting 1015 the microstructuring of the surface of the wafer 200, the surface coating 205 of the wafer 200 and sensitive functional elements are detected, which have a particularly sensitive coating that may be adversely affected by contact with the adhesive layer 125 of the wafer singulation film 100. The structuring 1020 of the microstructuring of the adhesive layer 125 of the wafer singulation film 100 is then performed based on the detected surface coating 205 and the sensitive functional elements. For this purpose, a microstructuring of the adhesive layer 125 complementary to the microstructuring of the surface of the wafer 200 is formed on the carrier film 105. The adhesive layer 125 is removed or passivated (see above) to match the surface coating 205 and the functional elements in order to prevent contact with the sensitive coating of the wafer 200.

When stretching 1015 the carrier film with a homogeneous adhesive layer 125 onto the tensioning frame 500, a tensioning frame 500 commonly used for singulating wafers is used. As a result, the upper side of the carrier film 105 is (almost) in one plane with the adhesive layer 125 in a pretensioned state. On the one hand, the pretensioning ensures that the film is flat, which is a prerequisite for precise optical processing by the laser. On the other hand, it is ensured that the adhesive regions of the wafer singulation film 100 do not “sag” on the wafer 200 or rest on it over a longer period of time. The pretensioning of the carrier film 105 in the tensioning frame 500 provides a sufficiently high mechanical restoring force, which reliably prevents prolonged contact between the non-adhesive regions of the wafer singulation film 100 and the wafer 200. The pretensioning is selected so that a mechanical resonance frequency of the clamped wafer singulation film 100 is between 50 and 100 Hz. By mechanically striking and analyzing the acoustic spectrum of the mechanical vibration of the wafer singulation film 100, it is possible to check whether the wafer singulation film 100 has been clamped in the tensioning frame 500 with sufficient tensioning. In this way, a particularly simple, reliable and precise microstructuring of the adhesive layer 125 is possible, for example using a laser micromachining system.

FIG. 6 shows a flow chart of an embodiment of the method according to the invention for singulating 2000 the wafer 200 with the wafer singulation film 100. Initially, the wafer singulation film 100 with the microstructured adhesive layer 125 is provided 2005 for the wafer 200 with the microstructured surface coating 205. As described above, the adhesive layer 125 has a microstructuring that is complementary to the microstructuring on the surface of the wafer 200.

The wafer 200 with the surface coating 205 is then aligned 2010 with the wafer singulation film 100 with the microstructured adhesive layer 125, so that the sensitive partial regions of the surface coating 205 with the functional elements of the wafer 200 overlap with the non-adhesive regions of the adhesive layer 125 of the wafer singulation film 100 with the microstructured adhesive layer. In other exemplary embodiments, the wafer singulation film 100 is aligned 2010 with the wafer 200. Alignment 2010 can, for example, be performed using an optical signal, wherein the wafer singulation film 100 is at least partially transparent for this purpose. Furthermore, the alignment 2010 can be carried out using a mechanical auxiliary device, which allows a particularly precise alignment of the wafer singulation film 100 to the wafer 200 or vice versa. Here, too, the aforementioned pretensioning of the prestructured wafer singulation film 100 in the tensioning frame 500 is very advantageous because it prevents the wafer singulation film from “sagging”, which prevents it from coming into undesired premature contact with the wafer 200 during the alignment process 2010.

The wafer 200 is then bonded 2015 to the wafer singulation film 100 with microstructured adhesive layer 125. Here, the surface of the wafer 200 sticks to the adhesive regions of the adhesive layer 125 of the wafer singulation film 100 in regions where no sensitive functional elements are present. The adhesion 2015 of the wafer 200 to the wafer singulation film 100 is carried out in particular in a directional manner, so that entrapment of air or another gas between the surface of the wafer 200 and the wafer singulation film 100 can be minimized or completely prevented. The pretensioning of the wafer singulation film 100 now ensures that the adhesive regions do not come or remain in contact with the surface of the wafer 100, or at least not for a long time.

Finally, the wafer 200 adhered to the wafer singulation film 100 with the microstructured adhesive layer 125 is singulated 2020 into a plurality of microstructured chips. The singulation 2020 can, for example, be carried out by sawing the wafer 200 or by so-called stealth dicing, wherein predetermined breaking points are first introduced into the wafer 200 by means of a laser and then a defined singulation of the wafer 200 into a plurality of microstructured chips is induced by expanding the wafer singulation film 100.

The microstructured chips resulting from the singulation 2020 of the wafer 200 are detached 2025 from the wafer singulation film 100 with the microstructured adhesive layer 125. Detaching 2025 can, for example, be automated using a pick-and-place robot. Detaching 2025 can be facilitated, if necessary, by previously exposing the singulation film 100 to ultraviolet radiation, which reduces the adhesive strength of the adhesive layer 125.

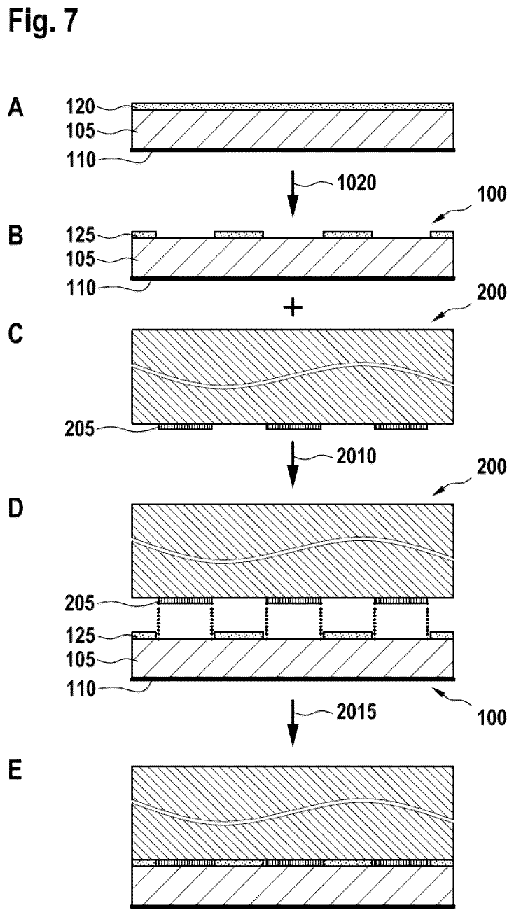

FIG. 7 shows schematically the implementation of the methods described above for manufacturing 1000 and singulation 2000 by means of sectional views. FIG. 7 A shows a carrier film 105 with a homogeneous adhesive layer 120 and a silicone coating 110 on the back, which serves as the starting point for the production of the wafer singulation film 100 according to the invention. FIG. 7 B shows the wafer singulation film 100 with structured adhesive layer 125 after structuring 1020. Reference is made to FIG. 1 A and its description. FIG. 7 C shows a wafer 200 with a microstructured surface coating 205, which is present in partial regions of the surface of the wafer 200. FIG. 7 D shows an arrangement of the wafer singulation film 100 shown in FIG. 7 B with the microstructured adhesive layer 125 and the wafer 200 shown in FIG. 7 C, which is present after alignment 2010. The partial regions of the wafer 200 with the surface coating 205 are aligned precisely complementary to the regions of the wafer singulation film 100 with the adhesive layer 125. FIG. 7 E shows a combination of the wafer 200 shown in FIG. 7 D and the wafer singulation film after adhesion 2015. The previously performed alignment 2010 can ensure that the surface coating 205 of the wafer 200 does not come into contact with the adhesive regions of the adhesive layer 125 of the wafer singulation film 100. In addition to the exact alignment, the pretensioning of the carrier film 100 in the tensioning frame 500 also contributes to this. Reference is made to FIGS. 3 A and 3 B and their description.

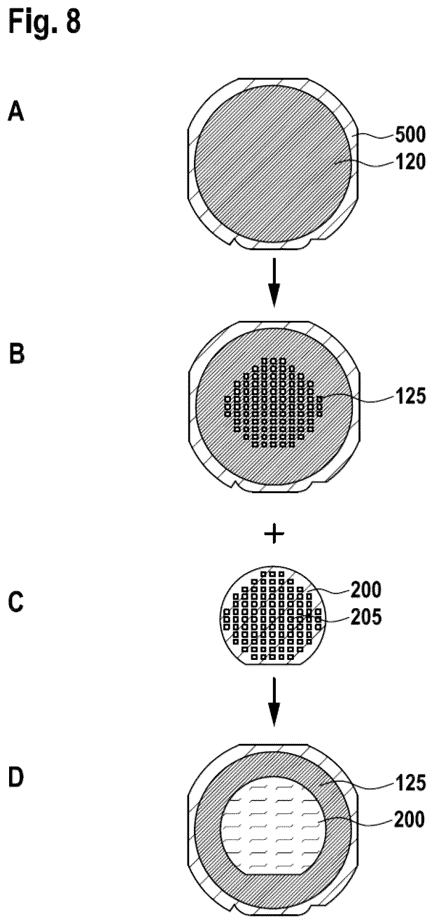

FIG. 8 shows in a schematic manner the implementation of the methods described above for manufacturing 1000 and singulation 2000 by means of top view illustrations. FIG. 8 A shows a carrier film 105 with a homogeneous adhesive layer 120, which is stretched with a sufficiently large tensioning on a tensioning frame 500 and serves as a starting point. FIG. 8 B shows the wafer singulation film 100 with structured adhesive layer 125 after structuring 1020. The microstructured adhesive layer 125 is characterized in particular by a grid-like arrangement of regions, each of which is square-shaped in this example, in which the adhesive layer has been removed and/or passivated in order to form the microstructured adhesive layer 125. FIG. 8 C shows a wafer 200 with a microstructured surface coating 205. The surface coating 205 is characterized in particular by a grid-shaped arrangement of regions, each of which is square-shaped in this example, in which the surface coating 205 is present. FIG. 8 D shows a combination of the wafer singulation film 100 shown in FIG. 8 B with the microstructured adhesive layer 125 on the tensioning frame 500 and the wafer 200 shown in FIG. 8 C after alignment 2010 and adhesion 2015.

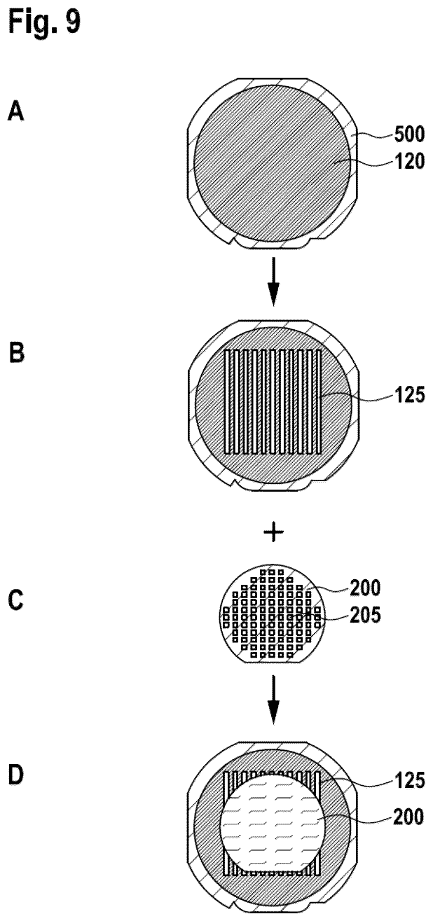

In addition to such a complementary structure of the surface coating 205 of the wafer and the structured adhesive layer 125, a partially complementary microstructuring of the adhesive layer 125 is also possible, as shown in the exemplary embodiment of FIG. 9.

FIG. 9 shows in a schematic manner the implementation of the methods described above for manufacturing 1000 and singulation 2000 by means of top view representations and differs from FIG. 8 only in that a strip-shaped, partially complementary microstructuring of the adhesive layer 125 is present.

The partially complementary microstructuring of the adhesive layer 125 shown in FIG. 9 is characterized by an arrangement of vertically strip-shaped regions oriented parallel to one another, in which the adhesive layer 125 has been removed and/or passivated. Such a strip-shaped microstructuring of the adhesive layer 125 can be produced in a particularly simple manner by means of a laser micromachining system. Reference is also made to FIG. 4 A and its description. The regions have a constant distance d from each other. This distance d corresponds to the horizontal distance in the grid-shaped arrangement of the regions of the surface coating 205 of the wafer 200, which in this example also have a square shape.

It may be provided that the non-adhesive regions with removed and/or passivated adhesive layer 125 are formed larger than the partial regions of the surface coating 205, on the one hand to allow a tolerance in the alignment 2010 of the wafer singulation film with the microstructured adhesive film 125 and the wafer 200 and on the other hand to establish a reliable adhesive bond between the wafer 200 and the adhesive film 125.

In addition, the wafer singulation film 100 preferably has an optical transparency in a predetermined wavelength range, at least in partial regions, in order to permit an optically based alignment 2010 of the wafer singulation film 100 and the wafer 200. This can be, for example, the visible wavelength range of electromagnetic radiation with wavelengths between 400 nm and 800 nm or a partial wavelength range thereof. It is advantageous that the structuring of the wafer singulation film is also optically recognizable, i.e. visible, in this optical spectral range, which enables the optically based alignment 2010 of the wafer singulation film 100 and the wafer 200.

1. A wafer singulation film for a wafer, comprising:
a carrier film which has an adhesive layer on one side,
wherein the adhesive layer has a microstructuring with adhesive regions and non-adhesive regions, and
wherein the microstructuring of the adhesive layer is complementary or at least partially complementary to a microstructuring on a surface of the wafer.

2. The wafer singulation film according to claim 1, wherein the non-adhesive regions have a lateral dimension in a range of from 30 μm to 3000 μm.

3. The wafer singulation film according to claim 1, wherein the non-adhesive regions have a lateral dimension in a range of from 100 μm to 1000 μm.

4. The wafer singulation film according to claim 1, wherein the microstructuring of the adhesive layer is achieved by at least partially removing the adhesive layer in the non-adhesive regions.

5. The wafer singulation film according to claim 1, wherein the microstructuring of the adhesive layer is achieved by passivating the adhesive layer in the non-adhesive regions.

6. The wafer singulation film according to claim 1, wherein the non-adhesive regions are in the form of strips.

7. The wafer singulation film according to claim 1, wherein the non-adhesive regions are arranged periodically in a predeterminable grid.

8. The wafer singulation film according to claim 1, wherein the wafer singulation film is clamped in a tensioning frame with a pretensioning.

9. A wafer system, comprising:
a wafer having a surface with a microstructuring; and
a wafer singulation film comprising:
a carrier film which has an adhesive layer on one side, the adhesive layer having a microstructuring with adhesive regions and non-adhesive regions, and the microstructuring of the adhesive layer being complementary or at least partially complementary to the microstructuring of the surface of the wafer.

10. A method for producing a wafer singulation film for a wafer comprising:
providing a carrier film having a homogeneous adhesive layer on one side,
structuring the adhesive layer with a microstructuring having adhesive regions and non-adhesive regions, wherein the microstructuring is formed complementary to a microstructuring on a surface of the wafer.

11. The method according to claim 10, further comprising:
detecting the microstructuring on the surface of the wafer before the structuring of the adhesive layer is carried out.

12. The method according to claim 10, further comprising:
clamping the carrier film with the adhesive layer in a tensioning frame with a pretensioning before the structuring of the adhesive layer is carried out.

13. The method according to claim 10, wherein the microstructuring of the adhesive layer is achieved by at least partially removing the adhesive layer in the non-adhesive regions.

14. The method according to claim 13, wherein the removal of the adhesive layer is carried out by shaving off using an ultrashort pulse laser.

15. The method according to claim 10, wherein the microstructuring of the adhesive layer is achieved by passivating the adhesive layer in the non-adhesive regions.

16. The method according to claim 15, wherein the passivation is carried out via ultraviolet radiation.

17. A method for using the wafer singulation film according to claim 1 for singulating chips of a wafer, the method comprising:
providing the wafer singulation film with the adhesive layer with microstructuring which is complementary to the microstructuring on the surface of the wafer;
aligning the wafer singulation film and the wafer with respect to one another such that the microstructuring of the adhesive layer matches the microstructuring on the surface of the wafer;
bonding the surface of the wafer and the wafer singulation film over the adhesive layer; and
singulating the wafer.
